(19) United States
(12) Patent Application Publication
(10) Pub. No.: US 2006/0012387 A1
(43) Pub. Date: Jan. 19, 2006

(54) Systems and methods for testing radio frequency identification tags

(75) Inventor: Wayne E. Shanks, Baltimore, MD (US)

Correspondence Address: STERNE, KESSLER, GOLDSTEIN & FOX PLLC, 1100 NEW YORK AVENUE, N.W., WASHINGTON, DC, 20005, US

(73) Assignee: Symbol Technologies, Inc., Holtsville, NY (US)

(21) Appl. No.: 11/169,306

(22) Filed: Jun. 29, 2005

Related U.S. Application Data
(60) Provisional application No. 60/583,402, filed on Jun. 29, 2004.

(51) Int. Cl. G01R 31/302; G01M 19/00; H04Q 5/22

(52) U.S. Cl. 324/750; 702/122; 340/10.1

(57) ABSTRACT

Methods and systems for testing tags in volume are described. According to a first embodiment, an array of radiation sources is present. Each radiation source in the array corresponds to a tag in a plurality of tags. A plurality of radiation sources in the array controllably emit radiation to their corresponding tag to inhibit operation of an integrated circuit of their corresponding tag. A first radiation source in the array does not emit radiation to its corresponding tag. The tag corresponding to the first radiation source is tested. In a second embodiment, an array of blocking elements is present. Each blocking element in the array corresponds to a tag in a plurality of tags. The blocking elements in the array controllably inhibit radiation from being incident upon corresponding tags. A first blocking element in the array inhibits radiation from being incident upon its corresponding tag. The tag corresponding to the first blocking element is tested.

### CROSS-REFERENCE TO RELATED APPLICATION

This application claims the benefit of U.S. Provisional Application No. 60/583,402, filed Jun. 29, 2004 (Atty. Dkt. No. 1689.0630000), which is incorporated herein by reference in its entirety.

### BACKGROUND OF THE INVENTION

1. Field of the Invention

The present invention relates to radio frequency identification tags, and more specifically to testing of radio frequency identification tags.

2. Background Art

Currently, radio frequency identification (RFID) tags manufactured in high volume are difficult to test. For example, in the presence of a large number of tags, such as in a tag assembly line, it may be difficult to isolate an individual tag for testing. In other words, a standard read signal used to test a tag in a population of tags not only powers the tag under test, but the other tags in range. Thus, the effectiveness of the tag test may be diminished by the possibility of responses from the other tags in range.

Spatial isolation of a particular tag under test is difficult to accomplish. In some test systems, near field cavity coupling (evanescent coupling) is used to spatially isolate the radio frequency signal/field used to test a tag to sub-wavelength dimensions. However, this is complex, expensive, and often does not work sufficiently to read one and only one tag.

Thus, what is needed is a method, system, and apparatus for improved testing of individual RFID tags.

### BRIEF SUMMARY OF THE INVENTION

Methods, systems, and apparatuses are described for the testing of radio frequency identification (RFID) tags alone or in the presence of other tags.

In an aspect of the present invention, methods and systems for testing tags in volume are described. According to a first embodiment, an array of radiation sources is present. Each radiation source in the array corresponds to a tag in a plurality of tags. A plurality of radiation sources in the array controllably emit radiation to their corresponding tag to inhibit operation of an integrated circuit of their corresponding tag. A first radiation source in the array does not emit radiation to its corresponding tag. The tag corresponding to the first radiation source is tested, as its operation is not inhibited by radiation. Thus, the tag may be reliably tested in an isolated manner, even in the presence of other tags.

Each tag in the array may be tested in this manner, by stopping the emission of radiation to the tag by the corresponding radiation source during testing of the tag.

According to a second embodiment, an array of blocking elements is present. Each blocking element in the array corresponds to a tag in a plurality of tags. A blocking element in the array controllably inhibits radiation emitted by a radiation source to allow operation of an integrated circuit of its corresponding tag. A first blocking element in the array inhibits radiation from being incident upon its corresponding tag. The tag corresponding to the first blocking element is tested, as its operation is not inhibited by radiation. Thus, the tag may be reliably tested in an isolated manner, even in the presence of other tags.

Each tag in the array may be tested in this manner, by inhibiting radiation from being incident upon the tag by the corresponding blocking element during testing of the tag.

These and other objects, advantages and features will become readily apparent in view of the following detailed description of the invention.

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a plan view of an example radio frequency identification (RFID) tag.

FIG. 2 shows an example web of tag substrates that is a continuous roll type.

FIG. 3 shows an addressable lighting system for radiating tags under test, according to an example embodiment of the present invention.

FIG. 4 shows a tag testing system including an addressable lighting system, according to an example embodiment of the present invention.

FIGS. 5 and 6 show an addressable lighting system that includes radiation sources for testing of a row of tags in a web, according to an example embodiment of the present invention.

FIG. 7 shows an addressable blocking system for inhibiting radiation from being incident upon tags under test, according to an example embodiment of the present invention.

FIG. 8 shows a tag testing system including an addressable blocking system, according to an example embodiment of the present invention.

FIGS. 9 and 10 show an addressable blocking system that includes blocking elements for testing of a row of tags in a web, according to an example embodiment of the present invention.

FIG. 11 shows a tag testing system in which an addressable lighting system and an addressable blocking system are controlled by a common controller, according to an example embodiment of the present invention.

FIG. 12 shows a tag testing system in which an addressable lighting system and an addressable blocking system are controlled by different controllers, according to an example embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

I. Overview

The present invention relates to the testing of individual RFID tags located in a group of RFID tags. Embodiments of the present invention use radiation sources to inhibit operation of tags. A single tag (or multiple tags, depending on the type of test) is not radiated, and thus its operation is not inhibited. This “isolated” tag is then tested, by any desired technique, for proper operation. For example, in an embodiment, the isolated tag may be tested by a reader that transmits a communication signal directed to the isolated tag, including “near-field” read or “far-field” read configurations.

According to embodiments of the present invention, individual RFID tags located in a group of tags may be isolated and tested that are much less than a wavelength of the communication signal away from each other.

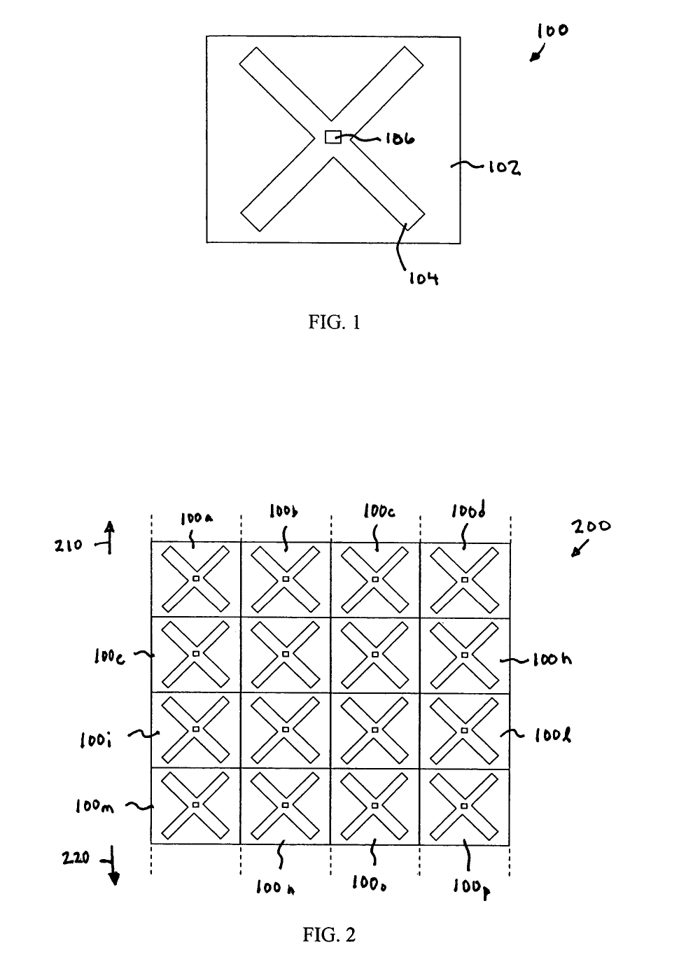

The present invention is applicable to any type of RFID tag. FIG. 1 shows a plan view of an example radio frequency identification (RFID) tag 100. Tag 100 includes a substrate 102, an antenna 104, and an integrated circuit (IC) 106. Antenna 104 is formed on a surface of substrate 102. IC 106 includes one or more integrated circuit chips/dies and/or other electronic circuitry. IC 106 is attached to substrate 102, and is coupled to antenna 104. IC 106 may be attached to substrate 102 in a recessed and/or non-recessed location. IC 106 controls operation of tag 100, and transmits signals to, and receives signals from RFID readers using antenna 104. The present invention is applicable to tag 100, and to other types of tags.

Volume production of RFID tags, such as tag 100, is typically accomplished on a printing web based system. For example, the tags are assembled in a web of substrates, which may be a sheet of substrates, a continuous roll of substrates, or other group of substrates. For example, FIG. 2 shows a plan view of an example web 200 that is a continuous roll type. For example, web 200 may extend further in the directions indicated by arrows 210 and 220. As shown in FIG. 2, web 200 includes a plurality of tags 100a-p. In the example of FIG. 2, the plurality of tags 100a-p in web 200 is arranged in a plurality of rows and columns. The present invention is applicable to any number of rows and columns of tags, and to other arrangements of tags.

On a web, such as web 200, RFID tags are typically assembled/placed as close to each other as possible to maximize throughput, thus making the process of reading and testing individual tags difficult. Inline testing of tags at the location of tag manufacture is key to reducing the cost of tags. For example, a problem in reading one tag in a dense array of tags is a problem of sub-wavelength imaging. In a manufacturing web, tags may be printed and assembled in a grid where the tag-to-tag spacing is much less that the wavelength of the radio waves used to excite the tags. Because of the close spacing, it is very difficult to localize a reader field to excite only one tag.

A shorter wavelength electromagnetic signal, that can be relatively easily localized to just one tag, can be used to read a tag under test. For example, in an embodiment, tags are stimulated with a shorter wavelength radio frequency signal. However, while the tag integrated circuits can potentially use and decode a wide band of RF frequencies, the tag antenna that couples to this signal will typically operate well at only the relatively long wavelength for which they were designed.

In another embodiment, a photosensitivity of the integrated circuit of the tag, which may be a silicon die or chip for example, is used. Integrated circuits are naturally sensitive to light. Photons from infrared frequencies through X-ray frequencies are able to generate photo-induced charge carriers (electrons-hole pairs). If the flux of light is high enough, these rogue photoelectrons and holes can inhibit the operation of the tag. This phenomenon can be exploited in the manufacturing process, such as in testing of tags.

In tag testing embodiments, a transmitter, such as a reader, can transmit a long wavelength RF read signal to the tags on the manufacturing web. In doing so, the tag under test will be activated (assuming it is operational) and many of its neighbors will also be activated. However, to ensure that only the tag under test is activated and read, in an embodiment of the present invention, all tags except for the tag under test are illuminated with a radiation source, such as a light source. Like radio waves, light is an electromagnetic wave, but has a wavelength of hundreds of nanometers, rather than tens of inches in wavelength for RF signals typically used to read tags. Because the wavelength of light is relatively short, focusing and directing light on a single tag is less complicated.

According to embodiments of the present invention, a photosensitivity property of a tag electrical circuit, such as IC 106, is used to enable testing of individual tags. In an embodiment, radiation is directed onto a tag to inhibit tag operation. For example, light may be directed onto the tags. Directing light onto the tag can inhibit tag operation despite the fact that the tag may be receiving sufficient RF power to operate.

II. Addressable Lighting System

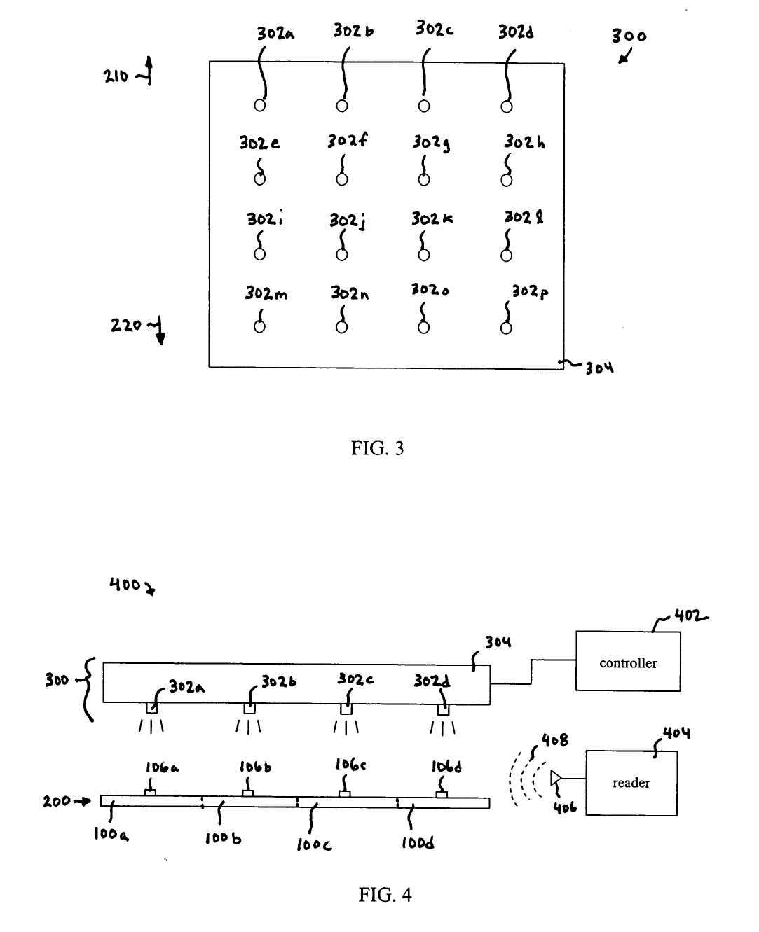

FIG. 3 shows a plan view of an addressable lighting system 300, according to an example embodiment of the present invention. System 300 can be used to inhibit tags in a plurality of tags (such as the plurality of tags 100a-p in web 200 shown in FIG. 2) from responding to read requests, except for a tag under test. For example, system 300 shows a four-by-four array of radiation sources 302a-p (e.g., light sources) that corresponds to the plurality of tags 100a-p shown in FIG. 2. Radiation sources 302 are attached to a radiation source mount 304. The array of radiation sources 302 of FIG. 3 may extend further in the directions of arrows 210 and 220 (i.e., “up” and “down” web) as needed to cover additional tags of web 200. Furthermore, system 300 can have any width of radiation sources 302 to cover webs 200 that are wider (i.e., “cross-web”) (e.g., have additional columns of tags) or are less wide (e.g., have fewer columns of tags). Furthermore, the pitch of radiation sources 302 (e.g., the distance between centers of adjacent radiation sources 302) can be adjusted for denser or less dense arrays of tags in web 200. Any number of radiation sources 302 may be present as needed, including ones, tens, hundreds, thousands, and more.

During test, all but one of radiation sources 302a-p emit radiation (e.g., light) that inhibits operation of all of the plurality of tags 100a-p of web 200, except for one. The one tag of tags 100a-p that does not receive radiation can be tested, as its operation is not inhibited. If that tag is found to be defective it can be subsequently sorted out in the production line. For example, a defective tag can be marked (e.g., inked), or its location can be stored (such as in storage of a computer system), for later locating of the defective tag and disposal or recycling.

FIG. 4 shows a tag testing system 400, according to an example embodiment of the present invention. In FIG. 4, system 400 includes addressable lighting system 300, a controller 402, and a reader 404. FIG. 4 shows a side view of addressable lighting system 300 and web 200. Controller 402 controls addressable lighting system 300, sending a signal or signals to addressable lighting system 300 to direct addressable lighting system 300 to emit radiation to inhibit operation of dies 106 of tags 100 in web 200, except for a particular tag 100 under test. Reader 404 includes an antenna 406, and is used to read or interrogate the particular tag 100 under test. Antenna 406 broadcasts a read signal 408 which is received by the particular tag 100, and receives a proper response from the particular tag 100, if the particular tag 100 is properly operational. Controller 402 controls addressable lighting system 300 to cycle through testing of all tags 100 in web 200 that are desired to be tested.

Reader 404 can test tags 100 according to any communications protocol/algorithm, as required by the particular application. For example, reader 404 can communicate with tags 100 according to a binary algorithm, a tree traversal algorithm, or a slotted aloha algorithm. Reader 404 can communicate with tags 100 according to a standard protocol, such as Class 0, Class 1, Gen 2, and any other known or future developed RFID communications protocol/algorithm.

In an example embodiment, by default, all radiation sources 302 emit light, thus shutting down all the tags. A command sent from controller 402 (which may be a computer, processor, logic, or other device, for example) shuts off one of the radiation sources 302, thus allowing the corresponding tag to be read and tested. By sequentially instructing different ones of radiation sources 302 to shut off, all the tags can be individually tested.

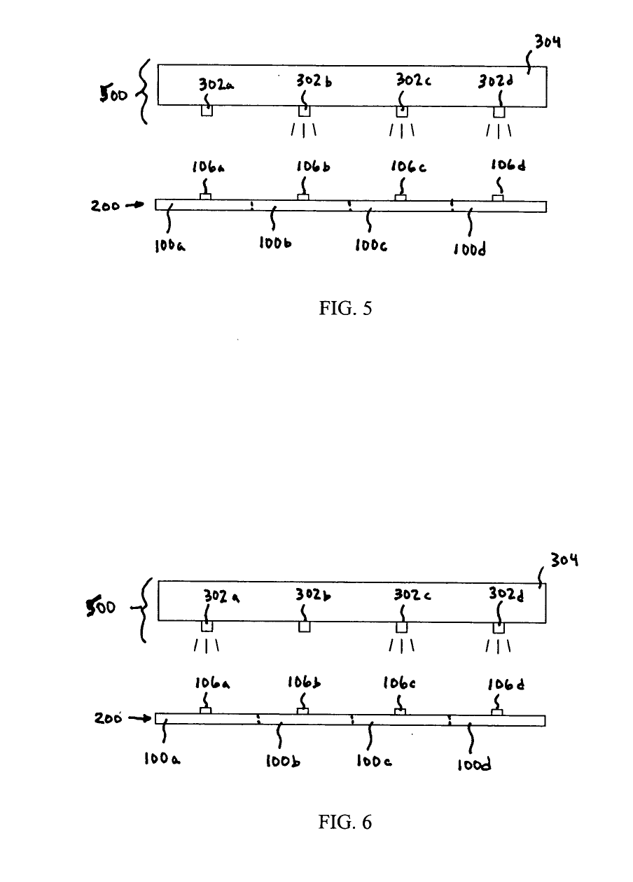

FIG. 5 shows an example addressable lighting system 500 that includes radiation sources 302a-d for testing of a row of tags 100a-d in web 200, according to an example embodiment of the present invention. Addressable lighting system 500 may include further rows of radiation sources 302 corresponding to further rows of tags 100 in web 200, to inhibit operation of selected tags 100. As shown in FIG. 5, in a first iteration of a tag test algorithm, radiation sources 302b-d are emitting radiation to inhibit operation of ICs 106b-d of tags 100b-d, under the direction of controller 402. Thus, tag 100a may be tested, as radiation source 302a is not emitting radiation, and therefore operation of IC 106a tag 100a is not inhibited.

In a next iteration of a tag test algorithm, as shown in FIG. 6, radiation sources 302a, 302c, and 302d are emitting radiation to inhibit operation of ICs 106a, 106c, and 106d of tags 100a, 100c, and 100d, respectively, under the direction of controller 402. Thus, tag 100b may be tested, as radiation source 302b is not emitting radiation, and therefore operation of IC 106b of tag 100b is not inhibited. This algorithm may be continued to test tags 100c and 100d, and further tags 100 in additional rows of web 200, if present.

Any type of radiation source can be used for radiation source 302. For example, silicon ICs are sensitive to light from infrared frequencies and greater frequencies. Thus, radiation sources 302 can be used that emit radiation/light somewhere in these frequencies. For example, radiation sources 302 that emit light in a band from infrared (˜800 nm) to red (˜600 nm), or emit light at short wave ultraviolet (>350 nm) may be used. For example, a radiation source can be a light emitting diode (LED), a liquid crystal display (LCD), a laser, or any other applicable type of radiation source.

III. Addressable Blocking System

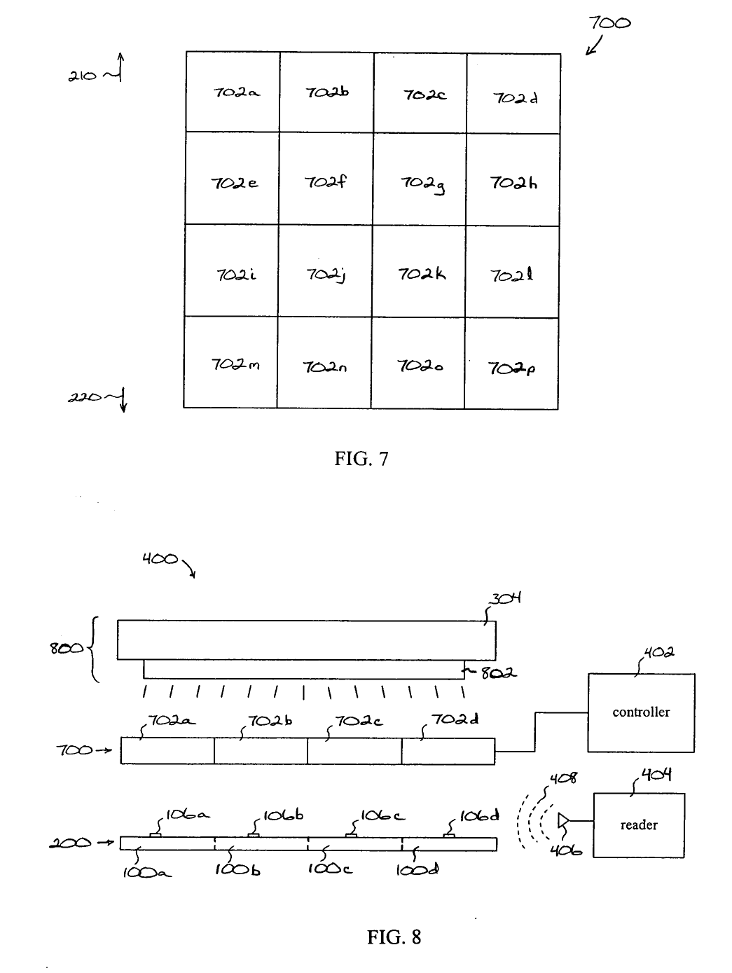

FIG. 7 shows a plan view of an addressable blocking system 700, according to an example embodiment of the present invention. System 700 can be provided between a radiation source (such as the radiation sources 302a-p shown in FIG. 3) and a plurality of tags (such as the plurality of tags 100a-p in web 200 shown in FIG. 2) to selectively block radiation that is emitted from the radiation source. For example, system 700 shows a four-by-four array of blocking elements 702a-p that corresponds to the plurality of tags 100a-p shown in FIG. 2. The array of blocking elements 702 of FIG. 7 may extend further in the directions of arrows 210 and 220 (i.e., “up” and “down” web) as needed to cover additional tags of web 200. Furthermore, system 700 can have any width of blocking elements 702 to cover webs 200 that are wider (i.e., “cross-web”) (e.g., have additional columns of tags) or are less wide (e.g., have fewer columns of tags). Furthermore, the pitch of blocking elements 702 (e.g., the distance between centers of adjacent blocking elements 702) can be adjusted for denser or less dense arrays of tags in web 200. Any number of blocking elements 702 may be present as needed, including ones, tens, hundreds, thousands, and more.

During test, all but one of blocking elements 702a-p allow radiation (e.g., light) to inhibit operation of all of the plurality of tags 100a-p of web 200, except for one. The one tag of tags 100a-p that does not receive radiation can be tested, as its operation is not inhibited. If that tag is found to be defective it can be subsequently sorted out in the production line. For example, a defective tag can be marked (e.g., inked), or its location can be stored, for later locating of the defective tag and disposal or recycling.

A blocking element 702 may block light in any of a variety of ways. According to an embodiment, a blocking element 702 blocks light based on the polarity of the blocking element 702. For example, the polarity of blocking elements 702 at steady state may be such that blocking elements 702 allow light to pass therethrough. The polarity of a blocking element 702 may be changed by a stimulus (e.g., an electrical, magnetic, or chemical stimulus). The stimulus may be applied to all but one of blocking elements 702, causing all of the blocking element 702 to block light, except for one. In another example, the polarity of blocking elements 702 at steady state may be such that blocking elements 702 block light. A stimulus may be applied to a blocking element 702, causing that blocking element to allow light to pass therethrough.

FIG. 8 shows tag testing system 400, according to another example embodiment of the present invention. In FIG. 8, system 400 includes lighting system 800, addressable blocking system 700, controller 402, and reader 404. FIG. 8 shows a side view of lighting system 800, addressable blocking system 700, and web 200. Lighting system 800 may include a single radiation source 802, as shown in FIG. 8, or any other suitable number of radiation sources.

Controller 402 controls addressable blocking system 700, sending a signal or signals to addressable blocking system 700 to direct addressable blocking system 700 to block radiation from being incident upon a particular tag 100 under test. For instance, addressable blocking system 700 may prevent radiation emitted from radiation source 802 from being incident upon the particular tag 100, while allowing the radiation to be incident upon other tags in web 200. Addressable blocking system 700 prevents radiation emitted from radiation source 802 from inhibiting operation of the particular tag 100.

Reader 404 includes an antenna 406, and is used to read or interrogate the particular tag 100 under test. Antenna 406 broadcasts a read signal 408 which is received by the particular tag 100, and receives a proper response from the particular tag 100, if the particular tag 100 is properly operational. Controller 402 controls addressable blocking system 700 to cycle through testing of all tags 100 in web 200 that are desired to be tested.

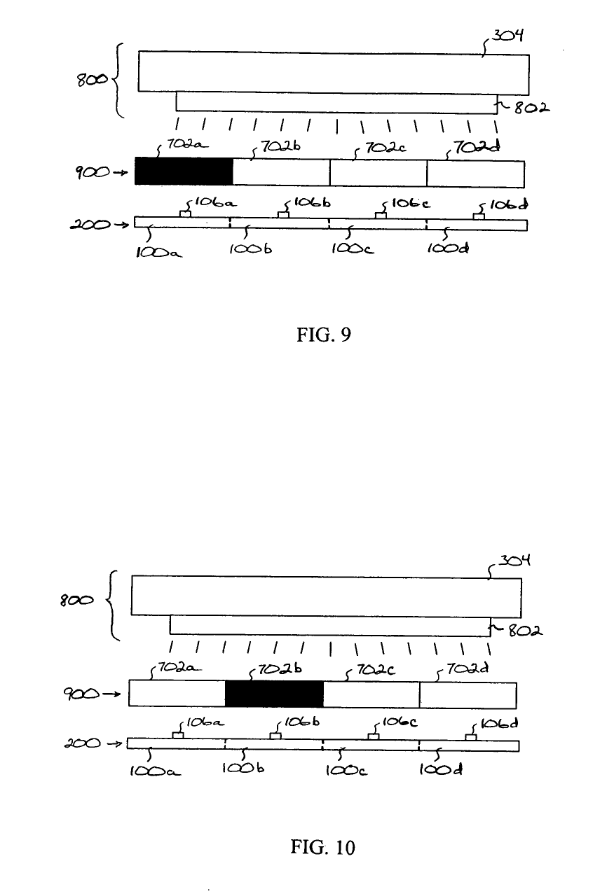

FIG. 9 shows an example addressable blocking system 900 that includes blocking elements 702a-d for testing of a row of tags 100a-d in web 200, according to an example embodiment of the present invention. Addressable blocking system 900 may include further rows of blocking elements 702 corresponding to further rows of tags 100 in web 200, to inhibit operation of selected tags 100. As shown in FIG. 9, in a first iteration of a tag test algorithm, blocking elements 702b-d are allowing radiation to inhibit operation of ICs 106b-d of tags 100b-d, under the direction of controller 402. Thus, tag 100a may be tested, as blocking element 702a is blocking radiation, and therefore operation of IC 106a tag 100a is not inhibited.

In a next iteration of a tag test algorithm, as shown in FIG. 10, blocking elements 702a, 702c, and 702d are allowing radiation to inhibit operation of ICs 106a, 106c, and 106d of tags 100a, 100c, and 100d, respectively, under the direction of controller 402. Thus, tag 100b may be tested, as blocking element 702b is blocking radiation, and therefore operation of IC 106b of tag 100b is not inhibited. This algorithm may be continued to test tags 100c and 100d, and further tags 100 in additional rows of web 200, if present.

Any type of blocking element can be used for blocking element 702. For example, an opaque or translucent object may be inserted between radiation source 802 and a tag 100 to inhibit radiation emitted from radiation source 802 from being incident upon the tag 100. The opaque or translucent object may be removed to allow radiation to inhibit operation of the tag 100.

According to an example embodiment, blocking element 702 is a material whose opacity is controllable, such as a polarized glass, according to an electrical or magnetic stimulus. In another example embodiment, blocking element 702 is a mechanical structure, such as a lever, that moves in and out of the radiation.

IV. Other Embodiments

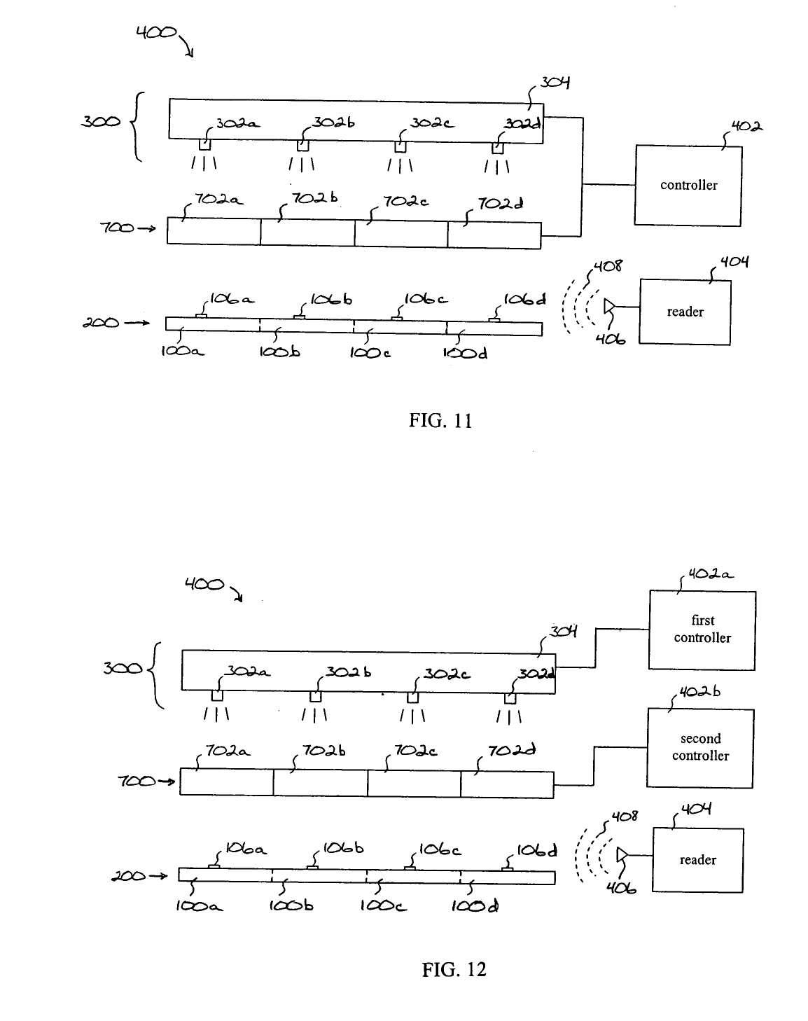

FIGS. 11 and 12 show that addressable lighting system 300 and addressable blocking system 700 may be included in the same tag testing system 400. In the example embodiment of FIG. 11, addressable lighting system 300 and addressable blocking system 700 are controlled by a common controller 402. Controller 402 controls addressable lighting system 300, sending a signal or signals to addressable lighting system 300 to direct addressable lighting system 300 to emit radiation to inhibit operation of dies 106 of tags 100 in web 200, except for a particular tag 100 under test. Controller 402 controls addressable blocking system 700 to direct addressable blocking system 700 to block radiation from being incident upon the particular tag 100 under test. For instance, addressable blocking system 700 may prevent radiation emitted from neighboring radiation sources 302 from inhibiting operation of the tag 100 under test. Addressable blocking system 700 may prevent radiation inadvertently emitted (e.g., leaking) from the radiation source 302 corresponding to the tag 100 under test from being incident upon the tag 100 under test.

As depicted in FIG. 11, controller 402 may use the same control signal to control addressable lighting system 300 and addressable blocking system 700. However, the scope of the present invention is not limited in this respect. According to an embodiment, addressable lighting system 300 receives a signal from controller 402 that is inverted as compared to the signal received by addressable blocking system 700. In another embodiment, addressable lighting system 300 serves as a backup system to addressable blocking system 700, or vice versa. For example, controller 402 may enable the addressable functionality of lighting system 300 or blocking system 700 and disable the addressable functionality of the other. If controller 402 disables the addressable functionality of lighting system 300, then radiation sources 302a-p are not selectively controlled. Instead, controller 402 controls radiation sources 302a-p using a common control signal. If controller 402 disables the addressable functionality of blocking system 700, then blocking elements 702a-p are not selectively controlled. Instead, controller 402 controls blocking elements 702 using a common control signal.

In an example embodiment, by default, all radiation sources 302 emit light and all blocking elements 702 allow light to pass therethrough, thus shutting down all the tags. A command sent from controller 402 shuts off one of the radiation sources 302 and/or instructs one of the blocking elements 702 to block light, thus allowing a corresponding tag to be read and tested. By sequentially instructing different ones of radiation sources 302 to shut off and/or different ones of blocking elements 702 to block light, all the tags can be individually tested.

In the example embodiment of FIG. 12, addressable lighting system 300 and addressable blocking system 700 are controlled by respective controllers 402a and 402b. For example, controllers 402a and 402b may operate independently of each other. In another example, controllers 402a and 402b may operate in synchronicity.

According to an embodiment, addressable lighting system 300 serves as a backup system to addressable blocking system 700, or vice versa. For example, first controller 402a, which controls addressable lighting system 300, and second controller 402b, which controls addressable blocking system 700, may be communicatively coupled. If first controller 402a detects an error associated with addressable lighting system 300, then first controller 402a may transmit an error signal to second controller 402b. Second controller 402b may then turn on the addressable functionality of addressable blocking system 700 or verify that the addressable functionality of addressable blocking system 700 is enabled. If second controller 402b detects an error associated with addressable blocking system 700, then second controller 402b may transmit an error signal to first controller 402a. First controller 402a may then turn on the addressable functionality of addressable lighting system 300 or verify that the addressable functionality of addressable lighting system 300 is enabled.

V. Conclusion

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents.

What is claimed is:

1. A system to test radio frequency identification (RFID) tags in volume, comprising:
an array of radiation sources, each radiation source in the array corresponding to a tag in a plurality of tags;
wherein a plurality of radiation sources in the array controllably emit radiation to corresponding tags to inhibit operation of integrated circuits of the corresponding tags.

2. The system of claim 1, further comprising:
a controller coupled to the array of radiation sources to control emission of radiation by the radiation sources.

3. The system of claim 1, wherein a first radiation source in the array does not emit radiation to a corresponding tag, and wherein the tag corresponding to the first radiation source is under test.

4. The system of claim 1, further comprising:
a reader that transmits a read signal to a tag that is under test of the plurality of tags.

5. The system of claim 1, wherein the plurality of tags are tags in a web.

6. The system of claim 5, further comprising a tag assembly apparatus that produces the tags in the web.

7. A method of testing radio frequency identification (RFID) tags in volume, comprising:
controlling an array of radiation sources, wherein each radiation source in the array corresponds to a tag in a plurality of tags;
wherein controlling the array includes
causing a plurality of radiation sources in the array to emit radiation to corresponding tags to inhibit operation of integrated circuits of the corresponding tags.

8. The method of claim 7, wherein controlling the array further comprises:
selecting a first radiation source of the array to stop emitting radiation to a first corresponding tag; and
testing operation of the first corresponding tag.

9. The method of claim 7, wherein controlling the array further comprises:
sequentially selecting radiation sources of the array to stop emitting radiation to their corresponding tags; and
testing operation of a tag when the corresponding radiation source has stopped emitting radiation.

10. A system for testing radio frequency identification (RFID) tags in volume, comprising:
an array of blocking elements, each blocking element of the array corresponding to a tag in a plurality of tags;
wherein blocking elements in the array controllably inhibit radiation from being incident upon corresponding tags.

11. The system of claim 10, further comprising:
a radiation source that emits the radiation upon the array of blocking elements.

12. The system of claim 11, wherein the radiation source includes an array of radiation sources, each radiation source corresponding to a blocking element in the array of blocking elements.

13. The system of claim 10, further comprising:
a controller coupled to the array of blocking elements to control opacity of the blocking elements.

14. The system of claim 10, wherein a first blocking element in the array inhibits the radiation from being incident upon a corresponding tag, and wherein the tag corresponding to the first blocking element is under test.

15. The system of claim 10, further comprising:
a reader that transmits a read signal to a tag that is under test of the plurality of tags.

16. The system of claim 10, wherein the plurality of tags are tags in a web.

17. The system of claim 16, further comprising a tag assembly apparatus that produces the tags in the web.

18. A method of testing radio frequency identification (RFID) tags in volume, comprising:
controlling an array of blocking elements, wherein each blocking element in the array corresponds to a tag in a plurality of tags;
wherein controlling the array includes
causing a first blocking element in the array to controllably inhibit radiation from being incident upon a first tag in the plurality of tags, the first tag corresponding to the first blocking element.

19. The method of claim 18, wherein controlling the array further comprises:
selecting a first blocking element of the array to inhibit the radiation from being incident upon a first corresponding tag; and
testing operation of the first corresponding tag.

20. The method of claim 18, wherein controlling the array further comprises:
sequentially selecting blocking elements of the array to inhibit radiation from being incident upon their corresponding tags; and
testing operation of a tag in response to the corresponding blocking element inhibiting radiation.
